(19) United States
(12) Patent Application Publication
(10) Pub. No.: US 2026/0162693 A1
(43) Pub. Date: Jun. 11, 2026

(54) SEMICONDUCTOR STORAGE DEVICE AND MANUFACTURING METHOD THEREOF

(71) Applicant: Kioxia Corporation, Tokyo (JP)

(72) Inventor: Kyosuke NANAMI, Yokkaichi Mie (JP)

(73) Assignee: Kioxia Corporation, Tokyo (JP)

(21) Appl. No.: 19/235,770

(22) Filed: Jun. 12, 2025

(30) Foreign Application Priority Data
Dec. 6, 2024 (JP) 2024-213879

(51) Int. Cl. G11C 5/06; H01L 23/00; H01L 23/48; H01L 25/18; H10B 43/10; H10B 43/27; H10B 43/35; H10B 43/50; H10D 30/01; H10D 30/69; H10D 80/30

(52) U.S. Cl. CPC G11C 5/063; H10B 43/10; H10B 43/27; H10B 43/35; H10D 30/0413; H10D 80/30; H10W 20/20; H10W 90/00; H10B 43/50; H10D 30/693; H10W 90/792

(57) ABSTRACT

A memory includes a stack of electrode films and first insulation films alternately stacked in a first direction. A first column body includes a semiconductor layer penetrating through the stack in the first direction and forms a memory cell. First pillar portions penetrate through the stack in the first direction and are an insulation material. Second pillar portions penetrate through the stack in the first direction, are a conductive material, and correspond to and are electrically connected to the electrode films, respectively. Assuming a connected electrode film connected to one of the second pillar portions as a boundary, a width of one of the second pillar portions in a plane perpendicular to the first direction is different between a pillar upper portion located above the connected electrode film in the first direction and a pillar lower portion located below the connected electrode film in the first direction.

### CROSS REFERENCE TO RELATED APPLICATIONS

This application is based upon and claims the benefit of priority from the prior Japanese Patent Application No. 2024-213879, filed on Dec. 6, 2024, the entire contents of which are incorporated herein by reference.

### FIELD

The embodiments of the present invention relate to a semiconductor storage device and manufacturing method thereof.

### BACKGROUND

A semiconductor storage device such as a NAND flash memory may include a three-dimensional memory cell array in which a plurality of memory cells are arranged three-dimensionally. There is a process of replacing sacrifice layers of a stack structure including insulation layers and the sacrifice layers with a conductive material to form a stack structure of word lines and the insulation layers (a replacement process). When the sacrifice layers are removed in this replacement process, the insulation layers may be bent by their own weight. To prevent the insulation layers from being bent, a plurality of support columns are provided which penetrate through the stack structure. However, since no support column is provided under a word line contact, there is still a concern about bending of the insulation layers.

In addition, when the support column is formed, a sacrifice material may be embedded in a contact hole for the word line contact once. If this sacrifice material is selected so as to make the sacrifice material function as the support column in the replacement process, the sacrifice material may become difficult to remove.

### BRIEF DESCRIPTION OF THE DRAWINGS

FIG. 1 is a sectional view illustrating a configuration example of a semiconductor storage device according to a first embodiment;

FIG. 2 is a plan view illustrating a stack;

FIG. 3 is a sectional view illustrating an example of a memory cell having a three-dimensional configuration;

FIG. 4 is a sectional view illustrating an example of the memory cells in a three-dimensional structure;

FIG. 5 is a sectional view illustrating a configuration example of contact regions in the stack according to the first embodiment;

FIG. 6 is a diagram illustrating an arrangement relation between a support column and a contact plug;

FIG. 7 is a diagram illustrating an arrangement relation between the support column and the contact plug in a comparative example in which a pillar lower portion is not provided;

FIG. 8 is a sectional view illustrating a configuration example of a semiconductor storage device according to a second embodiment;

FIG. 9 is a sectional view illustrating an example of a manufacturing method of the semiconductor storage device according to the second embodiment;

FIG. 10 is a sectional view illustrating the manufacturing method of the semiconductor storage device in continuation from FIG. 9;

FIG. 11 is a sectional view illustrating the manufacturing method of the semiconductor storage device in continuation from FIG. 10;

FIG. 12 is a sectional view illustrating the manufacturing method of the semiconductor storage device in continuation from FIG. 11;

FIG. 13 is a sectional view illustrating the manufacturing method of the semiconductor storage device in continuation from FIG. 12;

FIG. 14 is a sectional view illustrating the manufacturing method of the semiconductor storage device in continuation from FIG. 13;

FIG. 15 is a sectional view illustrating the manufacturing method of the semiconductor storage device in continuation from FIG. 14;

FIG. 16 is a sectional view illustrating the manufacturing method of the semiconductor storage device in continuation from FIG. 15;

FIG. 17 is a sectional view illustrating the manufacturing method of the semiconductor storage device in continuation from FIG. 16;

FIG. 18 is a sectional view illustrating the manufacturing method of the semiconductor storage device in continuation from FIG. 17;

FIG. 19 is a sectional view illustrating the manufacturing method of the semiconductor storage device in continuation from FIG. 18;

FIG. 20 is a sectional view illustrating the manufacturing method of the semiconductor storage device in continuation from FIG. 19;

FIG. 21 is a sectional view illustrating the manufacturing method of the semiconductor storage device in continuation from FIG. 20;

FIG. 22 is a sectional view illustrating the manufacturing method of the semiconductor storage device in continuation from FIG. 21;

FIG. 23 is a sectional view illustrating the manufacturing method of the semiconductor storage device in continuation from FIG. 22;

FIG. 24 is a sectional view illustrating the manufacturing method of the semiconductor storage device in continuation from FIG. 23;

FIG. 25 is a sectional view illustrating the manufacturing method of the semiconductor storage device in continuation from FIG. 24;

FIG. 26 is a sectional view illustrating the manufacturing method of the semiconductor storage device in continuation from FIG. 25;

FIG. 27 is a sectional view illustrating the manufacturing method of the semiconductor storage device in continuation from FIG. 26;

FIG. 28 is a sectional view illustrating the manufacturing method of the semiconductor storage device in continuation from FIG. 27;

FIG. 29 is a sectional view illustrating the manufacturing method of the semiconductor storage device in continuation from FIG. 28; and

FIG. 30 is a sectional view illustrating the manufacturing method of the semiconductor storage device in continuation from FIG. 29.

### DETAILED DESCRIPTION

In general, according to the embodiment, a semiconductor storage device comprises a stack including a plurality of electrode films and a plurality of first insulation films alternately stacked in a first direction. A first column body includes a semiconductor layer provided to penetrate through the stack in the first direction, and forms a memory cell at a crossing with one of the electrode films. A plurality of first pillar portions penetrate through the stack in the first direction and are made of an insulation material. A plurality of second pillar portions are made of a conductive material and penetrate through the stack in the first direction, and are electrically connected to the electrode films corresponding thereto, respectively. Assuming a connected electrode film connected to each of the second pillar portions among the electrode films as a boundary, a width of each of the second pillar portions in a plane perpendicular to the first direction is different between a pillar upper portion located above the connected electrode film in the first direction and a pillar lower portion located below the connected electrode film in the first direction.

Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

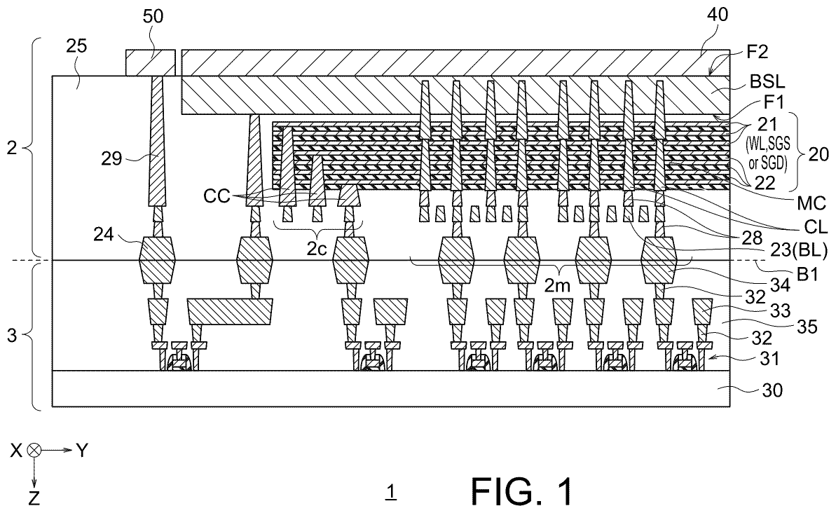

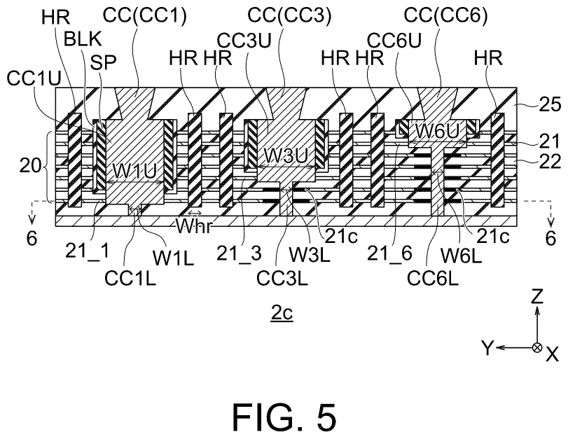

FIG. 1 is a sectional view illustrating a configuration example of a semiconductor storage device 1 according to a first embodiment. In the following descriptions, a stacking direction of a stack 20 is defined as the Z direction. One direction that crosses the Z direction, for example, at right angles is defined as the Y direction. One direction that crosses the Z direction and the Y direction, for example, at right angles is defined as the X direction. FIG. 1 illustrates the semiconductor storage device 1, assuming that the −Z direction is an upward direction. In sectional views in FIG. 5 and the subsequent drawings, the semiconductor storage device 1 is illustrated assuming that the +Z direction is the upward direction. In the present specification, the ±Z directions are examples of a first direction.

The semiconductor storage device 1 includes an array chip 2 having a memory cell array and a CMOS chip 3 having a CMOS circuit. The array chip 2 and the CMOS chip 3 are bonded to each other at a bonding surface B1 and are electrically connected to each other via wires joined at the bonding surface B1. FIG. 1 illustrates a state where the array chip 2 is provided on the CMOS chip 3.

The CMOS chip 3 includes a substrate 30, a transistor 31, a via 32, wires 33 and 34, and an interlayer dielectric film 35.

The substrate 30 is a semiconductor substrate such as a silicon substrate. The transistor 31 is an NMOSFET (Metal Oxide Semiconductor Field Effect Transistor) or a PMOSFET provided on the substrate 30. The transistor 31 constitutes a CMOS (Complementary MOS) circuit controlling a memory cell array 2m of the array chip 2, for example. The transistors 31 configure a logic circuit such as a sense amplifier, a row decoder, and a column decoder. A semiconductor element other than the transistor 31, for example, a resistor element and a capacitor element may be formed on the substrate 30.

The via 32 electrically connects the transistor 31 and the wire 33 to each other or the wire 33 and the wire 34 to each other. The wires 33 and 34 constitute a multilayer wiring structure in the interlayer dielectric film 35. The wire 34 is embedded in the interlayer dielectric film 35 and is exposed to be substantially flush with a surface of the interlayer dielectric film 35. The wires 33 and 34 are electrically connected to the transistor 31 or the like. A metal such as copper and tungsten is used for the via 32 and the wires 33 and 34. The interlayer dielectric film 35 covers and protects the transistor 31, the via 32, and the wires 33 and 34. An insulation film such as a silicon oxide film is used as the interlayer dielectric film 35.

The array chip 2 includes the stack 20, a column body CL, a source layer BSL, a metal layer 40, a contact plug CC, a contact plug 29, a bonding pad 50, wires 23 and 24, a via 28, and an interlayer dielectric film 25.

The stack 20 is provided above the transistor 31 and is located in the −Z direction with respect to the substrate 30. The stack 20 is configured by a plurality of electrode films 21 and a plurality of insulation films 22 alternately stacked in the +Z direction. The stack 20 constitutes a memory cell array together with the column body CL. A conductive metal, for example, tungsten is used for the electrode films 21. A silicon oxide film, for example, is used as the insulation film 22. The insulation film 22 insulates the electrode films 21 from each other. That is, the electrode films 21 are stacked while being insulated from each other. The number of each of the stacked electrode films 21 and the stacked insulation films 22 may be any number. The insulation film 22 may be a porous insulation film or an air gap, for example.

One or a plurality of the electrode films 21 at an upper end and a lower end in the Z direction of the stack 20 serve as a source-side selection gate SGS and a drain-side selection gate SGD, respectively. The electrode films 21 between the source-side selection gate SGS and the drain-side selection gate SGD serve as word lines WL. The word lines WL serve as gate electrodes of memory cells MC. The source-side selection gate SGS is a gate electrode of a source-side selection transistor. The drain-side selection gate SGD is a gate electrode of a drain-side selection transistor. The source-side selection gate SGS is provided in a −Z-side region of the stack 20. The drain-side selection gate SGD is provided in a +Z-side region of the stack 20. The −Z-side region refers to a region of the stack 20 farther from the CMOS chip 3 (closer to the metal layer 40), and the +Z-side region refers to a region of the stack 20 closer to the CMOS chip 3.

The semiconductor storage device 1 includes the memory cells MC connected in series between the source-side selection transistor and the drain-side selection transistor. The configuration in which the source-side selection transistor, the memory cells MC, and the drain-side selection transistor are connected in series is called “memory string” or “NAND string”. The memory string is connected to a bit line BL via the via 28, for example. The bit line BL is the wire 23 provided below the stack 20 and extending in the X direction. Therefore, the bit line BL is also described as the bit line 23 below.

The stack 20 includes the column bodies CL provided therein. Each column body CL extends in the stack 20 to penetrate therethrough in the stacking direction (the Z direction) of the stack 20 and is provided from the via 28 connected to the bit line 23 to the source layer BSL. The internal structure of the column body CL will be described later. In FIG. 1, a case is illustrated in which the column bodies CL are formed in two stages in the Z direction. However, the column bodies CL may be formed in three or more stages.

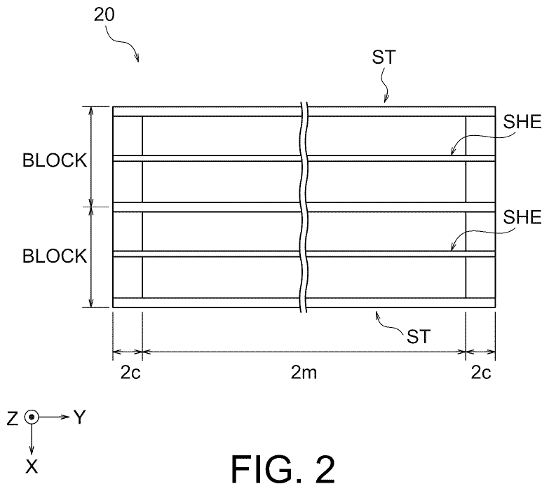

Although not illustrated in FIG. 1, a plurality of slits ST (see FIG. 2) are provided in the stack 20. The slits ST extend in the Y direction and penetrate through the stack 20 in the stacking direction (the Z direction) of the stack 20. Each slit ST is filled with an insulation film such as a silicon oxide film, and the insulation film is formed in a plate shape. The slits ST electrically divide the electrode films 21 of the stack 20. Alternatively, the inner wall of each slit ST may be covered with an insulation film such as a silicon oxide film, and a conductive material may further be embedded inside the insulation film. In this case, the conductive material can also serve as a source wire reaching the source layer BSL.

The source layer BSL is provided on the stack 20. The source layer BSL is provided to correspond to the stack 20. The stack 20 (the memory cell array 2m) is provided on a surface F1 side of the source layer BSL, and the metal layer 40 is provided on an opposite surface F2 side. The source layer BSL is connected to one ends of the column bodies CL in common to supply a common source voltage to the column bodies CL belonging to the same memory cell array 2m. That is, the source layer BSL serves as a common source electrode of the memory cell array 2m. A conductive material such as doped polysilicon is used for the source layer BSL. A metal material that is lower in resistance than the source layer BSL, for example, copper, aluminum, or titanium is used for the metal layer 40.

Meanwhile, the bonding pad 50 is provided above the surface F2 of the source layer BSL in a region where the source layer BSL is not provided. The bonding pad 50 is connected to a metal wire (not illustrated) or the like and receives power supply or a signal from outside of the semiconductor storage device 1. The bonding pad 50 is provided to be connected to one end in the Z direction of the contact plug 29. The bonding pad 50 is connected to the transistor 31 of the CMOS chip 3 via the contact plug 29, the wire 24, and the wire 34. External power supplied from the bonding pad 50 is supplied to the transistor 31. Alternatively, a signal is supplied to the transistor 31 via the bonding pad 50.

The contact plug CC is provided in a surrounding portion of the stack 20 and extends in the Z direction in the stack 20. The contact plug CC is electrically connected between one of the electrode films 21 (the word line WL) and the wire 24. The contact plugs CC are provided in a contact region 2c formed at an end of the stack 20 and are electrically connected to the electrode films 21, respectively. Each contact plug CC is provided for transferring a word-line voltage from the CMOS chip 3 to the corresponding electrode film 21. A metal such as copper and tungsten is used for the contact plug CC.

The contact plug 29 is provided in the surrounding portion of the stack 20 and extends in the Z direction in the interlayer dielectric film 25. The contact plug 29 is electrically connected between the bonding pad 50 and the wire 24. The contact plug 29 is used for supplying power supply or a signal from the bonding pad 50 to the array chip 2 or the CMOS chip 3. A metal such as copper and tungsten is used for the contact plug 29. The power supply is a power-supply voltage VDD or a reference voltage VSS lower than the power-supply voltage VDD (for example, a ground voltage), for example. The signal may be a control signal from outside, or write data or read data.

In the present embodiment, the array chip 2 and the CMOS chip 3 are formed independently of each other and bonded together at the bonding surface B1. Therefore, the transistor 31 is not provided in the array chip 2. Further, the stack 20 (the memory cell array 2m) is not provided in the CMOS chip 3.

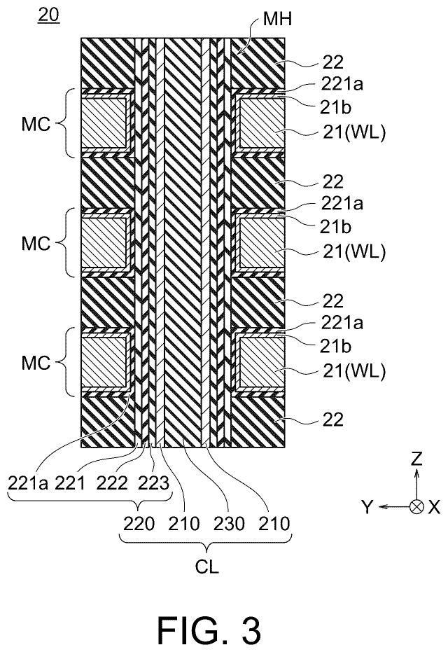

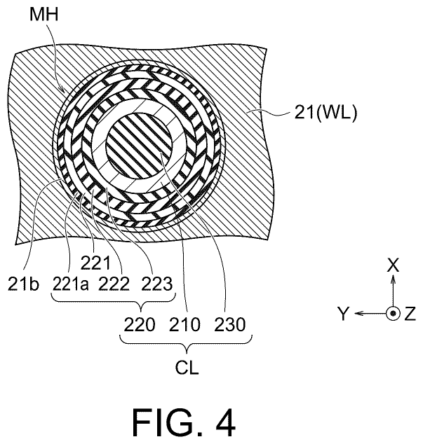

The via 28 and the wires 23 and 24 are provided in the +Z direction of the stack 20. The wires 23 and 24 are embedded in the interlayer dielectric film 25. The wire 24 is exposed to be substantially flush with the surface of the interlayer dielectric film 25. The wires 23 and 24 are electrically connected to a semiconductor body (210 in FIGS. 3 and 4) of the column body CL, for example. A metal such as copper and tungsten is used for the via 28 and the wires 23 and 24. The interlayer dielectric film 25 covers and protects the stack 20, the via 28, and the wires 23 and 24. An insulation film such as a silicon oxide film is used as the interlayer dielectric film 25.

The interlayer dielectric film 25 and the interlayer dielectric film 35 are bonded together at the bonding surface B1, and in association therewith, the wire 24 and the wire 34 are also joined together at the bonding surface B1 to be substantially flush therewith. Accordingly, the array chip 2 and the CMOS chip 3 are electrically connected to each other via the wires 24 and 34.

FIG. 2 is a plan view illustrating the stack 20. The stack 20 includes the contact region 2 c and the memory cell array 2m. The contact region 2 c is provided at an end of the stack 20, for example. The contact region 2c may be provided at the center of the stack 20. The memory cell array 2m is sandwiched between the contact regions 2c or is surrounded by the contact region 2c. The slit ST is provided from the contact region 2c at one end of the stack 20 to the contact region 2c at the other end of the stack 20 through the memory cell array 2m. A slit SHE is provided at least in the memory cell array 2m. The slit SHE is shallower than the slit ST in the Z direction and extends substantially parallel to the slit ST. The slit SHE electrically divides the electrode film 21 in the lower region of the stack 20 for each drain-side selection gate SGD. An insulation film such as a silicon oxide film is used as the slit SHE. Further, the slit ST may include a source wire electrically isolated from the electrode films 21 of the stack 20 and electrically connected to the source layer BSL.

A portion of the stack 20 sandwiched between two of the slits ST illustrated in FIG. 2 is called a block (BLOCK). The block is the minimum unit for erasing data, for example. The slits SHE are provided in the block. The stack 20 between the slit ST and the slit SHE is called a finger. The drain-side selection gate SGD is divided for each finger. Therefore, it is possible to place one finger in a block in a selected state by the drain-side selection gate SGD in data writing and data reading, while regarding one finger as a unit of writing or reading.

FIGS. 3 and 4 are sectional views illustrating an example of a memory cell having a three-dimensional configuration. Each of the column bodies CL is provided in a memory hole MH provided in the stack 20. Each column body CL penetrates through the stack 20 from one end of the stack 20 along the Z direction and is provided in the stack 20 and in the source layer BSL. The column bodies CL each include a semiconductor body 210, a memory film 220, and a core layer 230. The column body CL includes the core layer 230 provided at its center, the semiconductor body (semiconductor layer) 210 provided around the core layer 230, and the memory film 220 provided around the semiconductor body 210. The semiconductor body 210 extends in the stack 20 in the stacking direction (the Z direction). The semiconductor body 210 is electrically connected to the source layer BSL. The memory film 220 is provided between the semiconductor body 210 and the electrode film 21 and has a charge trap. The column bodies CL each of which is selected from the corresponding finger are connected to one bit line 23 in common via the vias 28 in FIG. 1. The column bodies CL are each provided in a region of the memory cell array 2m, for example. The column body CL is provided to penetrate through the stack 20 in the Z direction and constitutes the memory cell MC at a crossing with each electrode film 21.

As illustrated in FIG. 4, the shape of the memory hole MH in the X-Y plane is circular or elliptical, for example. A block insulation film 221a that constitutes a portion of the memory film 220 may be provided between the electrode film 21 and the insulation film 22. The block insulation film 221a is made of silicon oxide or metal oxide, for example. One example of the metal oxide is aluminum oxide. A barrier film 21b may be provided between the electrode film 21 and the insulation film 22 and between the electrode film 21 and the memory film 220. In a case where the electrode film 21 is made of tungsten, for example, the barrier film 21b is made of titanium nitride, for example. The block insulation film 221a prevents back tunneling of electric charges from the electrode film 21 toward the memory film 220. The barrier film 21b improves adhesion between the electrode film 21 and the block insulation film 221a.

The shape of the semiconductor body 210 is a tube with a bottom, for example. The semiconductor body 210 is made of polysilicon, for example. The semiconductor body 210 is made of undoped silicon, for example. The semiconductor body 210 may be made of p-type silicon. The semiconductor body 210 serves as a channel of each of a drain-side selection transistor, the memory cell MC, and a source-side selection transistor. That is, the memory cells MC include storage regions between the semiconductor body 210 and the electrode films 21 serving as the word lines WL, respectively, and are stacked in the Z direction. One ends of the semiconductor bodies 210 in the same memory cell array 2m are electrically connected to the source layer BSL in common.

The memory film 220 includes a cover insulation film 221, a charge trapping film 222, a tunnel insulation film 223, and the block insulation film 221a, for example. A portion of the memory film 220 other than the block insulation film 221a is provided between the inner wall of the memory hole MH and the semiconductor body 210. The shape of the memory film 220 is tubular, for example. Each of the charge trapping film 222 and the tunnel insulation film 223 extends in the Z direction.

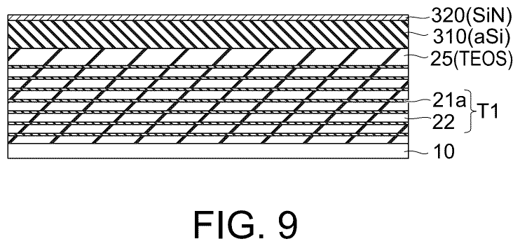

The cover insulation film 221 is provided between the insulation film 22 and the charge trapping film 222 and between the block insulation film 221a and the charge trapping film 222. The cover insulation film 221 contains silicon oxide, for example. The cover insulation film 221 protects the charge trapping film 222 from being etched when sacrifice films (21a in FIG. 9) are replaced with the electrode films 21 (in a replacement process).

The charge trapping film 222 is provided between the cover insulation film 221 and the tunnel insulation film 223. The charge trapping film 222 contains silicon nitride, for example, and has trap sites trapping electric charges therein. A portion of the charge trapping film 222, sandwiched between the electrode film 21 serving as the word line WL and the semiconductor body 210, constitutes a storage region of the memory cell MC as a charge trap. A threshold voltage of the memory cell MC is changed depending on whether electric charges are present in the charge trap or in accordance with the amount of electric charges trapped in the charge trap. Accordingly, the memory cell MC retains information.

The tunnel insulation film 223 is provided between the semiconductor body 210 and the charge trapping film 222. The tunnel insulation film 223 contains silicon oxide, or silicon oxide and silicon nitride, for example. The tunnel insulation film 223 is a potential barrier between the semiconductor body 210 and the charge trapping film 222. For example, when electrons are injected from the semiconductor body 210 to the charge trapping film 222 (a write operation) and when holes are injected from the semiconductor body 210 to the charge trapping film 222 (an erase operation), the electrons and the holes pass (tunnel) through the potential barrier by the tunnel insulation film 223, respectively.

The core layer 230 is embedded in a space within the tubular semiconductor body 210. The shape of the core layer 230 is columnar, for example. The core layer 230 contains silicon oxide, for example, and is insulating.

FIG. 5 is a sectional view illustrating a configuration example of the contact region 2c of the stack 20 according to the first embodiment. In FIG. 5, the contact region 2c of the stack 20 in FIG. 1 is illustrated upside down in the Z direction. That is, in FIG. 5 and the subsequent drawings, the upward direction is the +Z direction.

The contact region 2c includes the stack 20, a plurality of support columns HR, and the contact plugs CC.

The support columns HR as first pillar portions penetrate through the stack 20 in the Z direction. The support columns HR are made of an insulation material such as silicon oxide. The support columns HR are provided for supporting the insulation films 22 to prevent the insulation films 22 from being bent or recessed by their own weight when the electrode films 21 are removed in a replacement process described later.

The contact plugs CC as second pillar portions penetrate through the stack 20 in the Z direction. The contact plugs CC are made of a conductive material such as tungsten. The contact plugs CC are provided to correspond to the electrode films 21, respectively, and are each electrically connected to the corresponding electrode film 21. For example, a contact plug CC1 is electrically connected to an electrode film 21_1 at the lowermost layer among the electrode films 21 of the stack 20. A contact plug CC3 is electrically connected to a third electrode film 21_3 from the lowermost layer among the electrode films 21. A contact plug CC6 is electrically connected to a sixth electrode film 21_6 from the lowermost layer among the electrode films 21. The contact plugs CC connected to the other electrode films 21 are also provided, although not illustrated.

Each contact plug CC is electrically insulated from electrode films other than the connected electrode film (a connected word line) 21 that is electrically connected to that contact plug CC among the electrode films (word lines) 21. For example, the contact plug CC1 is electrically connected only to the connected electrode film 21_1 among the electrode films 21 and is electrically isolated from the other electrode films 21 (including 21_3 and 21_6). The contact plug CC3 is electrically connected only to the connected electrode film 21_3 among the electrode films 21 and is electrically isolated from the other electrode films 21 (including 21_1 and 21_6). The contact plug CC6 is electrically connected only to the connected electrode film 21_6 among the electrode films 21 and is electrically isolated from the other electrode films 21 (including 21_1 and 21_3). A contact plug CCn (n is an integer) is electrically connected only to a connected electrode film 21_n among the electrode films 21 and is electrically isolated from the other electrode films 21.

A block film BLK and a spacer SP are provided between each contact plug CC and the other electrode films 21 located above (in the +Z direction of) the connected electrode film 21 corresponding to that contact plug CC. The block film BLK and the spacer SP are made of an insulation material such as silicon oxide.

An insulation film 21c as a third insulation film is provided between a pillar lower portion CC3L or CC6L of each contact plug CC and each of the other electrode films 21 located below (in the −Z direction of) the connected electrode film 21 corresponding to that contact plug CC. The insulation film 21c is provided at the same height level as the electrode film 21 and is made of an insulation material such as silicon oxide. Since the connected electrode film 21_1 corresponding to the contact plug CC1 is at the lowermost layer of the electrode films 21, the insulation film 21c is not provided.

As described above, each of the contact plugs CC is electrically isolated from other electrode films 21 located above (in the +Z direction of) the connected electrode film 21 corresponding to that contact plug CC by the block film BLK and the spacer SP, assuming that connected electrode film 21 as a boundary. Each of the contact plugs CC is electrically isolated from other electrode films 21 located below (in the −Z direction of) the connected electrode film 21 corresponding to that contact plug CC by the insulation films 21c, assuming the connected electrode film 21 as a boundary.

Further, as illustrated in FIG. 5, the width (diameter) of the contact plug CC1 corresponding to the connected electrode film 21_1 is different between a pillar upper portion CC1U of the contact plug CC1 located above (in the +Z direction of) the connected electrode film 21_1 as a boundary and a pillar lower portion CC1L located below (in the −Z direction of) the connected electrode film 21_1. A width W1L of the pillar lower portion CC1L is smaller than a width W1U of the pillar upper portion CC1U.

The width (diameter) of the contact plug CC3 corresponding to the connected electrode film 21_3 is different between a pillar upper portion CC3U of the contact plug CC3 located above (in the +Z direction of) the connected electrode film 21_3 as a boundary and a pillar lower portion CC3L located below (in the −Z direction of) the connected electrode film 21_3. A width W3L of the pillar lower portion CC3L is smaller than a width W3U of the pillar upper portion CC3U.

The width (diameter) of the contact plug CC6 corresponding to the connected electrode film 21_6 is different between a pillar upper portion CC6U of the contact plug CC6 located above (in the +Z direction of) the connected electrode film 21_6 as a boundary and a pillar lower portion CC6L located below (in the −Z direction of) the connected electrode film 21_6. A width W6L of the pillar lower portion CC6L is smaller than a width W6U of the pillar upper portion CC6U.

The same applies to the other contact plugs CC that are not illustrated. Accordingly, assuming the connected electrode film 21_n connected to the contact plug CCn among the electrode films 21 as a boundary, the width of the contact plug CCn is different between a pillar upper portion CCnU located above (in the +Z direction of) the connected electrode film 21_n and a pillar lower portion CCnL located below (in the −Z direction of) the connected electrode film 21_n. A width WnL of the pillar lower portion CCnL is smaller than a width WnU of the pillar upper portion CCnU.

The width WnL of the pillar lower portion CCnL may be substantially equal to a width Whr of the support column HR.

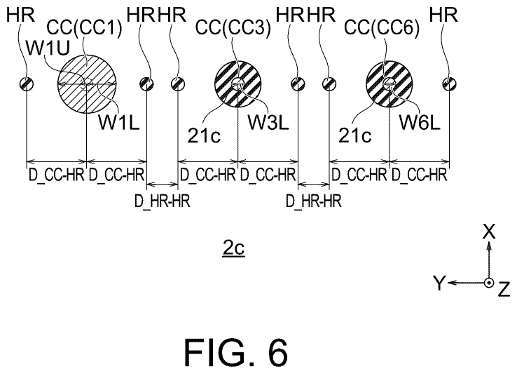

FIG. 6 is a diagram illustrating an arrangement relation between the support column HR and the contact plug CC. FIG. 6 is a view of a section along a line 6-6 in FIG. 5, that is, a cross-section cut along a plane perpendicular to the Z direction (the X-Y plane) along the connected electrode film 21_1 at the lowermost layer of the stack 20 when viewed in the Z direction. In FIG. 6, illustrations of the connected electrode film 21_1 itself are omitted.

As illustrated in FIG. 6, in the connected electrode film 21_1 at the lowermost layer of the stack 20, the pillar upper portion CC1U appears regarding the contact plug CC1, and the pillar lower portions CC3L and CC6L appear regarding the contact plugs CC3 and CC6, respectively. Accordingly, in the connected electrode film 21_1 at the lowermost layer of the stack 20, the width W1U of the contact plug CC1 is larger than the widths W3L and W6L of the other contact plugs CC3 and CC6.

Further, in the connected electrode film 21_1 at the lowermost layer of the stack 20, a first distance D_CC-HR between the support column HR and the contact plug CC adjacent to each other is larger than a second distance D_HR-HR between the support columns HR adjacent to each other with no contact plug CC sandwiched therebetween. The first distances D_CC-HR are substantially equal to each other. The second distances D_HR-HR are substantially equal to each other.

According to the present embodiment, as illustrated in FIGS. 5 and 6, the contact plug CCn has the pillar lower portion CCnL below (in the −Z direction of) the connected electrode film 21_n. Assuming that the connected electrode film 21_n is a boundary, the pillar lower portion CCnL extends from the pillar upper portion CCnU of the contact plug CCn downwards (to the −Z direction) and is provided to a position lower than the electrode film 21 at the lowermost layer of the stack 20. With this configuration, the pillar lower portion CCnL of the contact plug CCn can support, together with the support column HR, the insulation films 22 located below the pillar upper portion CCnU to prevent the insulation films 22 from being bent or recessed by their own weight when the electrode films 21 are removed in a replacement process described later.

If the pillar lower portion CCnL is not provided, the insulation films 22 located below the pillar upper portion CCnU illustrated in FIG. 5 cannot be supported.

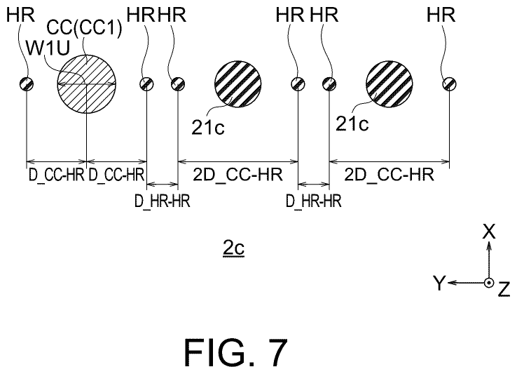

For example, FIG. 7 is a diagram illustrating an arrangement relation between the support column HR and the contact plug CC in a comparative example in which the pillar lower portion CCnL is not provided. As illustrated in FIG. 7, in the connected electrode film 21_1 at the lowermost layer of the stack 20, the contact plugs CC3 and CC6 do not appear. In this case, the distance between the support columns HR adjacent to each other with the contact plug CC3 or CC6 sandwiched therebetween is 2×D_CC-HR, that is, becomes wider. In this case, the insulation films 22 of the stack 20 can be bent easily in the replacement process.

Meanwhile, the contact plug CCn according to the present embodiment has the pillar lower portion CCnL below (in the −Z direction of) the connected electrode film 21_n. Accordingly, the support column HR and the pillar lower portion CCnL can support the insulation films 22 at a relatively narrow pitch. Accordingly, it is possible to prevent the insulation films 22 located below the pillar upper portion CCnU from being bent or recessed in the replacement process.

### Second Embodiment

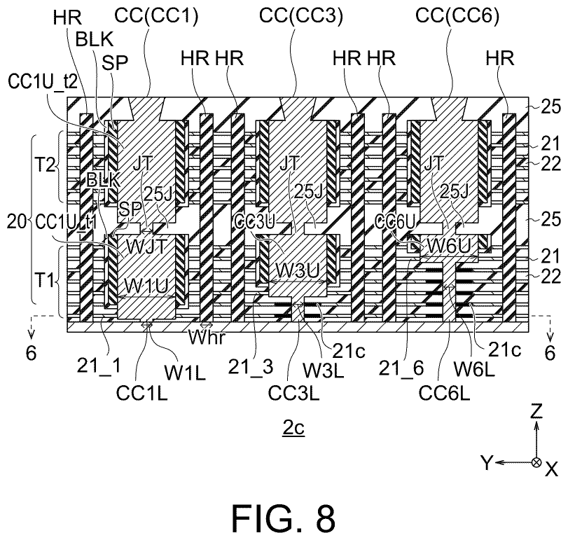

FIG. 8 is a sectional view illustrating a configuration example of the semiconductor storage device 1 according to a second embodiment. In the second embodiment, the stack 20 includes a first stack portion T1 and a second stack portion T2.

The first and second stack portions T1 and T2 each have the electrode films 21 and the insulation films 22 stacked in the Z direction. The second stack portion T2 is stacked above (in the +Z direction of) the first stack portion T1.

The contact plugs CC penetrate through the first and second stack portions T1 and T2 and, in the first stack portion T1, have a configuration identical to that in the first embodiment.

The contact plugs CC also include the contact plug CCn connected to any of the electrode films 21 in the second stack portion T2, although not illustrated. In this case, the connected electrode film 21_n connected to the contact plug CCn is located in the second stack portion T2. Therefore, the pillar lower portion CCnL of the contact plug CCn is a portion of the contact plug CCn located below (in the −Z direction of) the connected electrode film 21_n in the second stack portion T2. The pillar upper portion CCnU of the contact plug CCn is a portion of the contact plug CCn located above (in the +Z direction of) the connected electrode film 21_n in the second stack portion T2. Also in the second embodiment, the width WnL of the pillar lower portion CCnL is smaller than the width WnU of the pillar upper portion CCnU.

With this configuration, the pillar lower portion CCnL of the contact plug CCn can support the insulation films 22 located below the height of the connected electrode film 21_n in a replacement process also in the second embodiment. Accordingly, it is possible to prevent the insulation films 22 from being bent or recessed.

In addition, in a case where the connected electrode film 21_n is in the first stack portion T1 as illustrated in FIG. 8, a joint JT of the contact plug CC located between the first stack portion T1 and the second stack portion T2 is narrowed. That is, the width of the contact plug CC in the X-Y plane is W1U in the first and second stack portions T1 and T2 and is WJT in the joint JT between the first stack portion T1 and the second stack portion T2. The width WJT is smaller than the width W1U. Accordingly, the contact plugs CC have a shape that is narrowed in the joint JT. The joint JT does not necessarily have a narrowed shape.

To the contrary, the insulation film 25 between the first stack portion T1 and the second stack portion T2 protrudes towards the center of the corresponding contact plug CC in the X-Y plane. Accordingly, the contact plug CC has a shape that is narrowed in the joint JT. To prevent the contact plug CC from being electrically isolated in the joint JT, the insulation film 25 has an opening in a region of the contact plug CC.

As explained above, even when the stack 20 includes a plurality of the stack portions T1 and T2, effects of the present embodiment are not lost. The number of the stack portions included in the stack 20 is not limited.

Next, a manufacturing method of the semiconductor storage device 1 according to the present embodiment is described.

FIGS. 9 to 30 are sectional views illustrating an example of the manufacturing method of the semiconductor storage device 1 according to the second embodiment. Here, a manufacturing method of a formation region (2c) of the contact plugs CC for the electrode films 21 (the word lines) is illustrated, but illustrations of a manufacturing method of the memory cell array 2m including the column bodies CL are omitted.

First, a plurality of sacrifice films 21a and the insulation films 22 are alternately stacked on a substrate 10 in the +Z direction to form the stack portion T1. The sacrifice films 21a are made of a material having etching selectivity with respect to the insulation films 22, for example, silicon nitride. The insulation films 22 are made of an insulation material such as silicon oxide.

Next, the insulation film 25 is formed on the stack portion T1, and thereafter mask members 310 and 320 are formed on the insulation film 25. The insulation film 25 is configured by a silicon oxide film formed by using TEOS, for example. The mask member 310 is made of a material having etching selectivity with respect to a silicon oxide film and a silicon nitride film, for example, amorphous silicon. The mask member 320 is made of a material such as silicon nitride. In this manner, the structure illustrated in FIG. 9 is obtained.

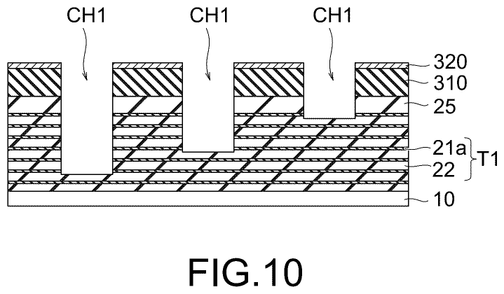

Next, as illustrated in FIG. 10, a contact hole CH1 is formed in the formation region of the contact plug CC by using a lithography technique and an etching technique. The contact hole CH1 is formed to extend in the −Z direction to a position shallower (higher) than the height of the connected electrode film 21_n corresponding to the contact plug CCn by one layer. Since the electrode films 21 have not been formed yet in this stage, the contact hole CH1 does not reach the sacrifice film 21a corresponding to the connected electrode film 21_n and is formed to the depth (a first depth) of the insulation film 22 located at a position shallower (higher) than that sacrifice film 21a by one layer.

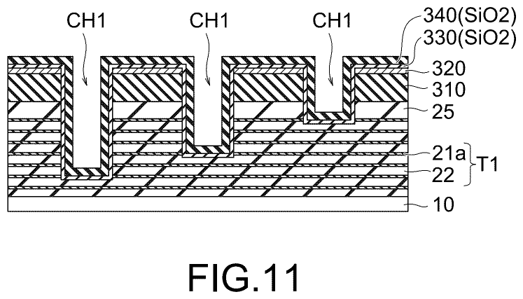

Next, as illustrated in FIG. 11, a block film 330 and a spacer film 340 are formed on the mask member 320 and on the inner wall of the contact hole CH1. The block film 330 and the spacer film 340 are made of an insulation material such as silicon oxide.

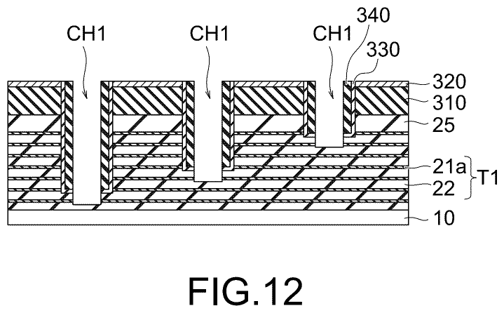

Next, as illustrated in FIG. 12, the block film 330 and the spacer film 340 are anisotropically etched back, so that the block film 330 and the spacer film 340 at the bottom of the contact hole CH1 are removed with the block film 330 and the spacer film 340 on the side surface of the contact hole CH1 left. Further, the sacrifice film 21a and the insulation film 22 that are located directly below the bottom of the contact hole CH1 are anisotropically etched, so that the contact hole CH1 is formed to extend in the −Z direction to a position deeper (lower) than the depth of the connected electrode film 21_n corresponding thereto by one layer. Since the electrode films 21 have not been formed yet in this stage, the contact hole CH1 penetrates through the sacrifice film 21a corresponding to the connected electrode film 21_n and is formed to the depth (a second depth) of the insulation film 22 located at a position deeper (lower) than that sacrifice film 21a by one layer.

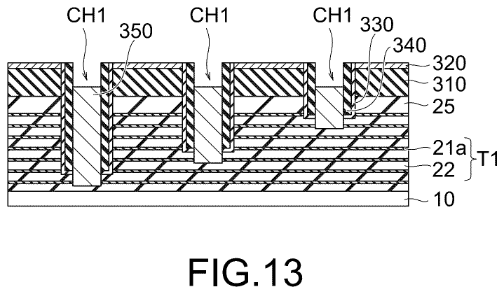

Next, a sacrifice film 350 is embedded in the contact hole CH1. As illustrated in FIG. 13, the sacrifice film 350 is etched back to the height of the mask member 310 or the insulation film 25. The sacrifice film 350 is made of a material having etching selectivity with respect to silicon, silicon oxide, and silicon nitride, for example, carbon.

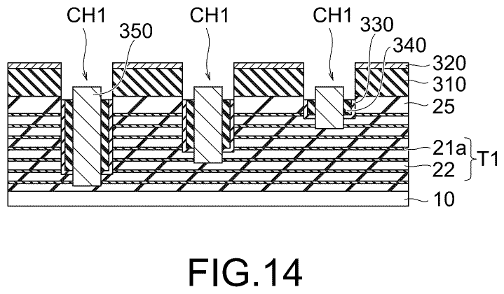

Next, as illustrated in FIG. 14, the block film 330 and the spacer film 340 are etched by wet etching, so that the sacrifice film 350 is made to protrude to some extent from the block film 330 and the spacer film 340 in the contact hole CH1.

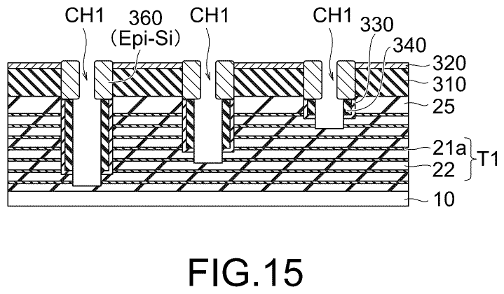

Next, as illustrated in FIG. 15, after the sacrifice film 350 is removed, a narrowing film 360 is formed in the opening of the contact hole CH1 to make the opening narrower. The narrowing film 360 is a silicon film formed by epitaxial growth, for example. In a case where the mask member 310 is made of amorphous silicon, the silicon film can be made to selectively grow by epitaxial growth on the sidewall of the mask member 310 exposed in the contact hole CH1. Further, when the sacrifice film 350 is removed, the sacrifice film 21a located at the height position of the connected electrode film 21 corresponding to each contact hole CH1 is exposed at the bottom of that contact hole CH1.

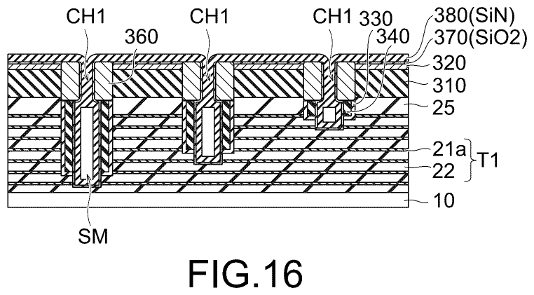

Next, as illustrated in FIG. 16, a barrier film 370 is formed thin on the mask member 320 and on the inner wall of the contact hole CH1. The barrier film 370 is made of an insulation material such as silicon oxide. The barrier film 370 covers the sacrifice film 21a exposed at the bottom of each contact hole CH1.

That is, the sidewall of the contact hole CH1 corresponding to the pillar upper portion CCnU located above the sacrifice film 21a at which the connected electrode film 21 is to be formed is protected by the block film 330 and the spacer film 340. The sacrifice film 21a at which the connected electrode film 21 is to be formed is protected by the barrier film 370.

Subsequently, a sacrifice film 380 is formed on the barrier film 370. The sacrifice film 380 is formed to close the opening of the contact hole CH1 and leave a seam or a void (hereinafter, simply “seam”) SM in the contact hole CH1. The sacrifice film 380 can easily be removed by etching because it has the seam SM therein.

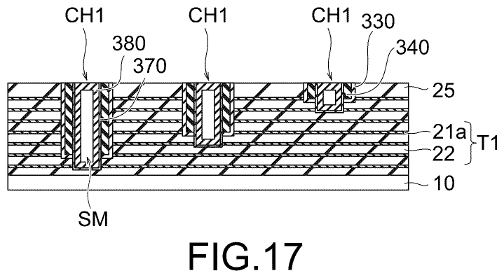

Next, the surface of the structure is flattened by CMP (Chemical Mechanical Polishing) or the like. Accordingly, as illustrated in FIG. 17, the mask members 310 and 320 and the barrier film 370 and the sacrifice film 380 thereon are removed, so that the surfaces of the insulation film 25 and the sacrifice film 380 are exposed.

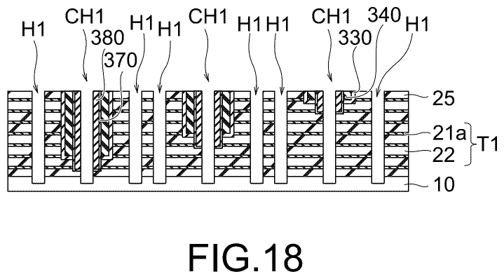

Next, the contact hole CH1, a hole H1 for the support column HR, and a memory hole (not illustrated) are formed by using a lithography technique and an etching technique. As illustrated in FIG. 18, the sacrifice film(s) 21a and the insulation film(s) 22 that are located directly below the bottom of the contact hole CH1 are anisotropically etched via the seam SM. Accordingly, the contact hole CH1 is processed to penetrate through the stack portion T1. The hole H1 for the support column HR is arranged around the contact hole CH1 and is formed to penetrate through the stack portion T1 in the −Z direction. At this time, the memory hole may also be formed to penetrate through the stack portion T1 in the −Z direction, although not illustrated.

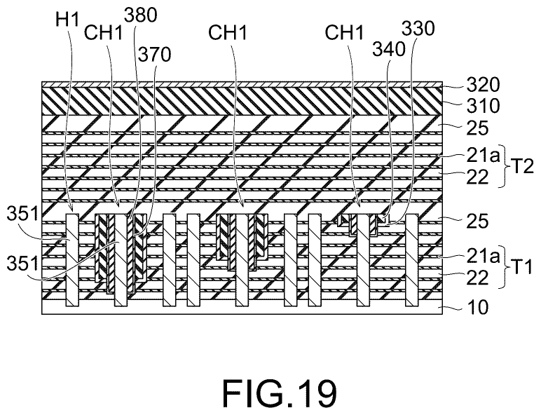

Next, as illustrated in FIG. 19, a sacrifice film 351 is formed in the contact hole CH1, the hole H1, and the memory hole.

Next, the insulation film 25 is further deposited on the sacrifice film 351 in the contact hole CH1, the hole H1, and the memory hole.

Subsequently, the sacrifice films 21a and the insulation films 22 are alternately stacked on the insulation film 25 in the +Z direction to form the stack portion T2. The insulation film 25 and the mask members 310 and 320 are formed on the stack portion T2 in an identical manner to the processes of forming the stack portion T1. In this manner, the structure illustrated in FIG. 19 is obtained.

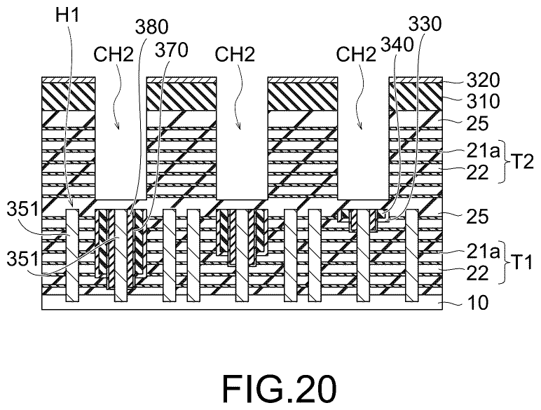

Next, as illustrated in FIG. 20, contact holes CH2 penetrating through the stack portion T2 in the +Z direction and reaching the insulation film 25 under the stack portion T2 are formed above the contact holes CH1 to correspond to the contact holes CH1, respectively.

In a case where the connected electrode film 21_n is formed in the stack portion T1, as illustrated in FIG. 20, the contact holes CH2 are formed to reach the insulation film 25 under the stack portion T2. Meanwhile, in a case where the connected electrode film 21_n is formed in the stack portion T2, the contact holes CH2 are formed to the depth of a position at which the connected electrode film 21_n is to be formed in the stack portion T2, although not illustrated. In this case, the sacrifice film 351 is provided to penetrate through the stack portion T1 in the Z direction under the contact holes CH2.

Next, similarly to the block film 330 and the spacer film 340 in the stack portion T1, the block film 330 and the spacer film 340 are formed on the sidewall of each contact hole CH2 in the stack portion T2. The block film 330 and the spacer film 340 at the bottom of the contact hole CH2 are removed by being etched back.

Next, similarly to the narrowing film 360 in the contact hole CH1 in the stack portion T1, the narrowing film 360 is selectively formed in the opening of the contact hole CH2 to make the opening of the contact hole CH2 narrower.

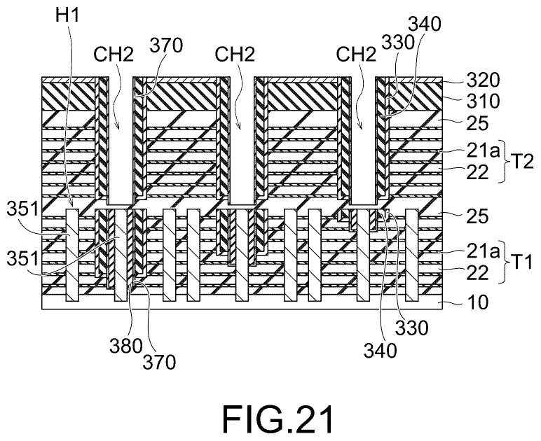

Next, the barrier film 370 is formed on the spacer film 340 on the sidewall of each contact hole CH2, and then the barrier film 370 at the bottom of the contact hole CH2 is removed by being etched back. The insulation film 25 at the bottom of the contact hole CH2 is etched to some extent by using the mask member 320 and the barrier film 370 as mask. In this manner, the structure illustrated in FIG. 21 is obtained. In this stage, the insulation film 25 in the joint JT is left between the contact hole CH2 and the sacrifice film 351 in the contact hole CH1.

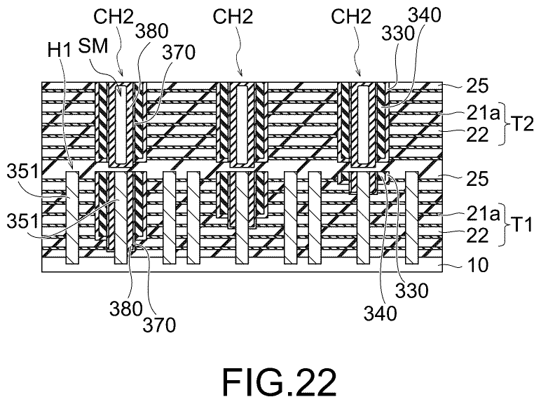

Next, similarly to the sacrifice film 380 in the contact hole CH1 in the stack portion T1, the sacrifice film 380 is also formed in the contact hole CH2. That is, as illustrated in FIG. 22, the sacrifice film 380 is formed to close the opening of the contact hole CH2 and leave the seam SM in the contact hole CH2. Accordingly, since the sacrifice film 380 has the seam SM therein, the sacrifice film 380 can easily be removed by etching.

Next, the surface of the structure is flattened by CMP or the like. Accordingly, the mask members 310 and 320 and the barrier film 370 and the sacrifice film 380 thereon illustrated in FIG. 21 are removed, so that the surfaces of the insulation film 25 and the sacrifice film 380 are exposed. In this manner, the structure illustrated in FIG. 22 is obtained.

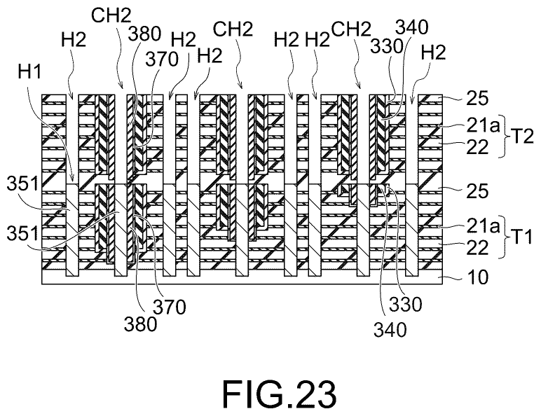

Next, the contact hole CH2, a hole H2 for the support column HR, and a memory hole (not illustrated) are formed by using a lithography technique and an etching technique. As illustrated in FIG. 23, the insulation film 25 directly below the bottom of the contact hole CH2 is anisotropically etched via the seam SM. Accordingly, the contact hole CH2 penetrates through the stack portion T2 and communicates with the contact hole CH1. At the bottom of the contact hole CH2, the sacrifice film 351 in the contact hole CH1 is exposed. The hole H2 for the support column HR is formed around the contact hole CH2. The hole H2 is formed to penetrate through the stack portion T2 in the −Z direction and communicates with the hole H1. At the bottom of the hole H2, the sacrifice film 351 in the hole H1 is exposed. At this time, the memory hole may also be formed to penetrate through the stack portion T2 in the −Z direction, although not illustrated. The memory hole in the stack portion T2 communicates with the memory hole that has been formed in the stack portion T1. At the bottom of the memory hole in the stack portion T2, the sacrifice film in the memory hole that has been formed in the stack portion T1 is exposed.

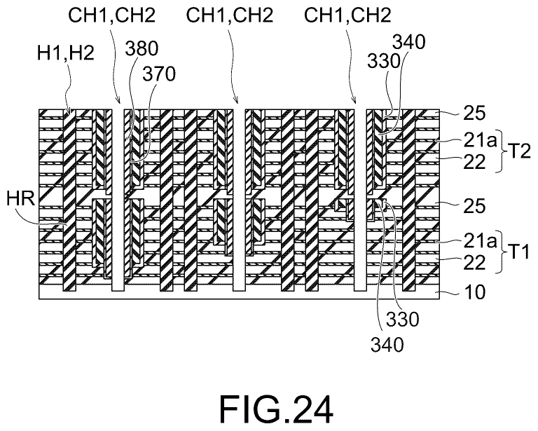

Next, as illustrated in FIG. 24, the sacrifice film 351 in the contact holes CH1 and CH2, the holes H1 and H2, and the memory holes is removed. At this time, in a lower portion of the contact hole CH1, the sacrifice film 21a located below the barrier film 370 is exposed on the sidewall of the contact hole CH1.

Next, as illustrated in FIG. 24, the memory hole and the contact holes CH1 and CH2 are covered with resist by using a lithography technique, and an insulation material is formed in the holes H1 and H2. In this manner, the support column HR is formed in each of the holes H1 and H2.

Next, after the resist is removed, the support column HR and the contact holes CH1 and CH2 are covered with resist by using a lithography technique again, and the memory film 220, the semiconductor body 210, and the core layer 230 in FIGS. 3 and 4 are formed in the memory hole. Accordingly, the column body CL is formed in the memory hole. Formation of the column body CL may be performed before formation of the support column HR.

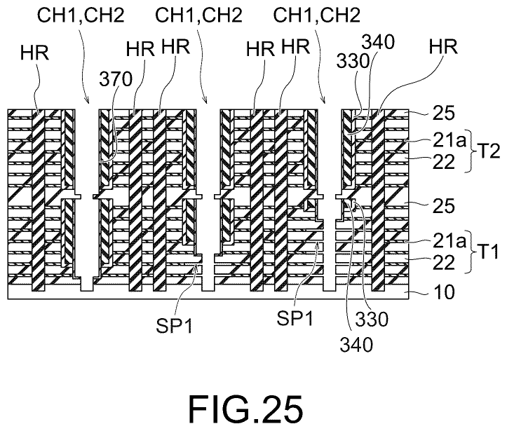

Next, after the resist is removed, the support column HR and the column body CL are covered with resist by using a lithography technique again, and the sacrifice film 380 in the contact holes CH1 and CH2 is removed. At this time, by wet etching, the sacrifice film 21a that is located below the barrier film 370 and is exposed in the contact hole CH1 is isotropically etched simultaneously with removal of the sacrifice film 380. The sacrifice film 380 can easily be removed by etching because it has the seam SM therein. Accordingly, as illustrated in FIG. 25, a first space SP1 is formed between the insulation films 22 located below the barrier film 370 and adjacent to each other in the Z direction.

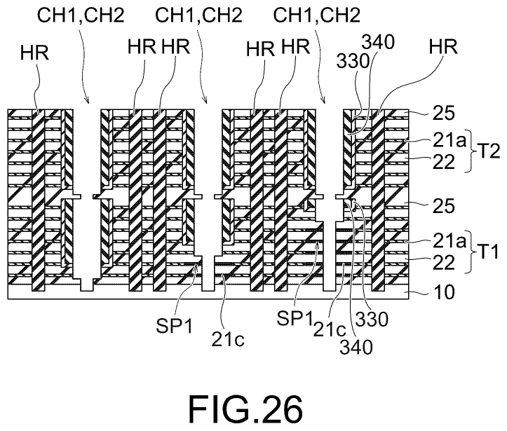

Next, as illustrated in FIG. 26, the insulation film 21c is embedded in the first space SP1. The insulation film 21c is made of an insulation material having etching selectivity with respect to the sacrifice film 21a, for example, silicon oxide.

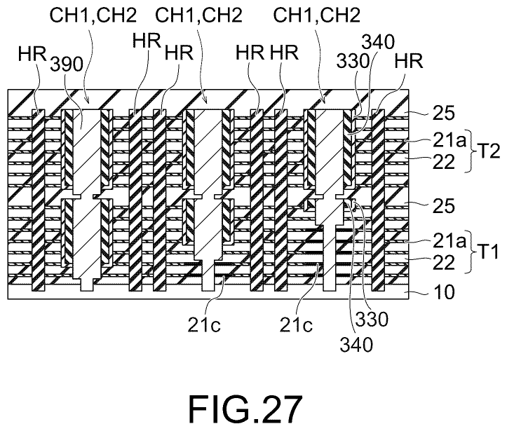

Next, as illustrated in FIG. 27, after the barrier film 370 is removed, a sacrifice film 390 is formed in the contact holes CH1 and CH2. The sacrifice film 390 is made of a material having etching selectivity with respect to a silicon oxide film and a silicon nitride film, for example, amorphous silicon. Subsequently, the material for the insulation film 25 (e.g., silicon oxide) is further deposited on the stack portion T2.

Next, slits (ST in FIG. 2) penetrating through the stack portions T1 and T2 (the stack 20) in the −Z direction and reaching the substrate 10 are formed by using a lithography technique and an etching technique.

Next, the sacrifice films 21a are removed from the stack portions T1 and T2 via the slits ST by wet etching or the like, so that a second space SP2 is formed between the insulation films 22 adjacent to each other in the Z direction.

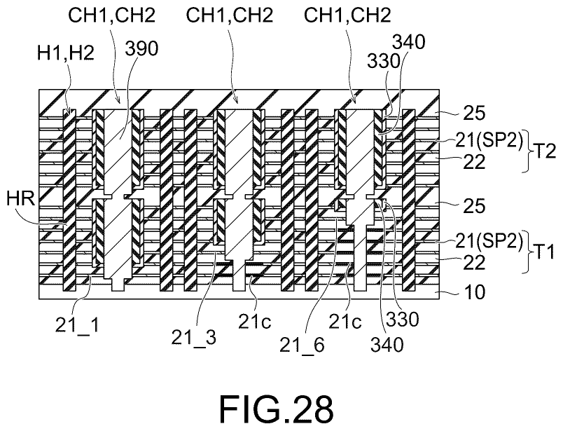

Next, as illustrated in FIG. 28, the electrode film 21 is formed in the second space SP2. The electrode film 21 is made of a conductive material such as tungsten. The process of replacing the sacrifice film 21a with the electrode film 21 in this manner is called “replacement process”. The electrode film 21 serves as a control electrode (a word line) of the memory cell MC.

As illustrated in FIG. 28, the connected electrode films 21_1, 21_3, and 21_6 among the electrode films 21 are in contact with the sacrifice film 390 embedded in the contact holes CH1 and CH2 respectively corresponding thereto. The electrode films 21 located above (in the +Z direction of) the connected electrode film 21_1, 21_3, or 21_6 are isolated from the sacrifice film 390 embedded in the contact holes CH1 and CH2 by the spacer 340 and the block film 330. Further, the electrode films 21 located below (in the −Z direction of) the connected electrode film 21_3, or 21_6 are isolated from the sacrifice film 390 embedded in the contact holes CH1 and CH2 by the insulation film 21c.

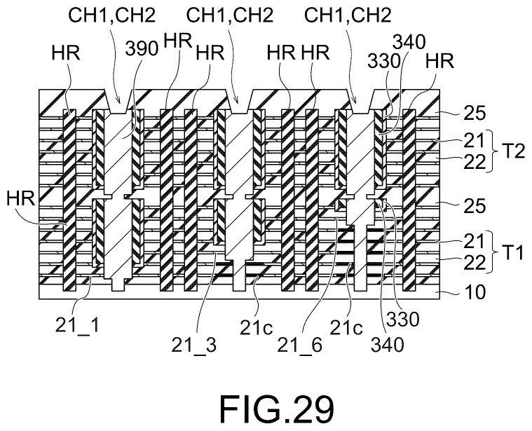

Next, as illustrated in FIG. 29, the insulation film 25 on the contact holes CH1 and CH2 are selectively removed by lithography and etching.

Next, the sacrifice film 390 in the contact holes CH1 and CH2 is removed by wet etching or the like. At this time, on the sidewall of the contact hole CH1 or CH2, the connected electrode film 21_1, 21_3, or 21_6 corresponding thereto is exposed.

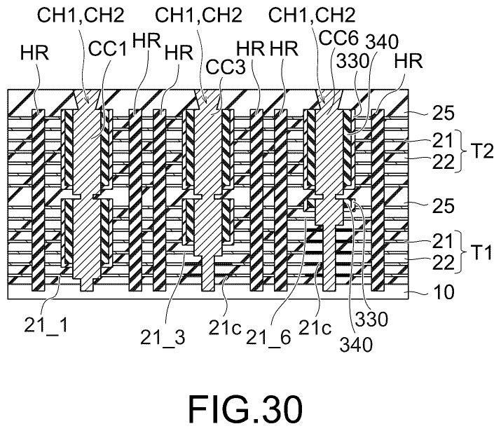

Next, as illustrated in FIG. 30, the material for the contact plug CC is embedded in the contact holes CH1 and CH2. The contact plug CC is made of a conductive material such as tungsten. The contact plug CC is electrically connected to the connected electrode film 21_1, 21_3, or 21_6 exposed in the contact hole CH1 or CH2.

As illustrated in FIG. 30, the connected electrode films 21_1, 21_3, and 21_6 among the electrode films 21 are in contact with the contact plugs CC1, CC3, and CC6 respectively corresponding thereto. The electrode films 21 located above (in the +Z direction of) the connected electrode film 21_1, 21_3, or 21_6 are electrically isolated from the contact plug CC1, CC3, or CC6 by the spacer 340 and the block film 330. The electrode films 21 located below (in the −Z direction of) the connected electrode film 21_3, or 21_6 are electrically isolated from the contact plug CC1, CC3, or CC6 by the insulation film 21c.

Thereafter, a multilayer wiring layer and an interlayer dielectric film (23 to 25 and 28 in FIG. 1) are formed above the stack portion T2. Accordingly, an array wafer having a plurality of array chips is completed.

Meanwhile, a CMOS wafer having a CMOS chip is formed separately from the array wafer. For example, a plurality of semiconductor elements such as transistors are formed on a semiconductor substrate, and an interlayer dielectric film is formed to cover the semiconductor elements. Further, a wiring layer electrically connected to the semiconductor elements and partly exposed from the interlayer dielectric film is formed.

The memory wafer and the CMOS wafer are bonded to each other at the bonding surface B1 in FIG. 1, and the wiring layer on the CMOS wafer side and contacts on the array wafer side are electrically connected to each other.

Thereafter, the substrate 10 of the memory wafer is removed, and the metal layer 40 and the bonding pad 50 illustrated in FIG. 1 are formed. Further, the memory wafer and the CMOS wafer bonded to each other are cut into semiconductor chips in a dicing process. Accordingly, the semiconductor storage device 1 illustrated in FIG. 1 is completed.

By the manufacturing processes described above, the semiconductor storage device 1 according to the second embodiment can be formed.

The manufacturing method of the semiconductor storage device 1 according to the first embodiment can easily be understood from the manufacturing method according to the second embodiment.

For example, the sacrifice film 351 is formed in the contact hole CH1 and the hole H1 by the processes described with reference to FIGS. 9 to 18.

The processes of forming the stack portion T2 described with reference to FIGS. 19 to 23 are omitted.

Thereafter, as described with reference to FIG. 24, the support column HR and the column body CL are formed.

Further, the contact plug CC is formed in the contact hole CH1 by the replacement process and the like described with reference to FIGS. 25 to 30.

Other manufacturing processes according to the first embodiment may be identical to the manufacturing processes according to the second embodiment. Accordingly, the semiconductor storage device 1 according to the first embodiment illustrated in FIG. 5 can be formed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a stack including a plurality of electrode films and a plurality of first insulation films alternately stacked in a first direction;
a first column body provided to penetrate through the stack in the first direction, including a semiconductor layer, and forming a memory cell at a crossing with one of the electrode films;
a plurality of first pillar portions penetrating through the stack in the first direction and made of an insulation material; and
a plurality of second pillar portions penetrating through the stack in the first direction, made of a conductive material, and corresponding to and electrically connected to the electrode films, respectively, wherein
assuming a connected electrode film connected to one of the second pillar portions among the electrode films as a boundary, a width of one of the second pillar portions in a perpendicular plane perpendicular to the first direction is different between a pillar upper portion located above the connected electrode film in the first direction and a pillar lower portion located below the connected electrode film in the first direction.

2. The device of claim 1, wherein the width of one of the second pillar portions in the perpendicular plane perpendicular to the first direction is smaller in the pillar lower portion than in the pillar upper portion.

3. The device of claim 1, wherein in the perpendicular plane in the electrode films at a lowermost layer of the stack, a width of a part of the second pillar portions is larger than a width of another part of the second pillar portions.

4. The device of claim 1, wherein in the perpendicular plane in the electrode films at a lowermost layer of the stack, a first distance between the first pillar portion and the second pillar portion adjacent to each other is larger than a second distance between the first pillar portions adjacent to each other with no second pillar portion sandwiched therebetween.

5. The device of claim 1, wherein second distances between the first pillar portions adjacent to each other with no second pillar portion sandwiched therebetween are substantially equal to each other.

6. The device of claim 4, wherein second distances between the first pillar portions adjacent to each other with no second pillar portion sandwiched therebetween are substantially equal to each other.

7. The device of claim 1, wherein
the stack includes a first stack portion and a second stack portion each including the electrode films and the first insulation films stacked in the first direction, and
the width of one of the second pillar portions in the perpendicular plane perpendicular to the first direction is smaller in a joint between the first stack portion and the second stack portion than in the first and second stack portions.

8. The device of claim 1, further comprising a second insulation film provided between one of the electrode films located below the connected electrode film in the first direction and the pillar lower portion.

9. The device of claim 8, wherein
the first insulation film is a silicon oxide film, and
the second insulation film is a silicon nitride film.

10. A manufacturing method of a semiconductor storage device, comprising:
forming a first stack portion by alternately stacking a plurality of first sacrifice films and a plurality of first insulation films in a first direction;
forming a plurality of first holes in the first stack portion for the first sacrifice films, respectively, the first holes each extending in the first direction to a first depth of one of the first insulation films which is shallower than a corresponding one of the first sacrifice films by one layer;
forming a first material film on a sidewall of one of the first holes;
anisotropically etching one of the first sacrifice films which is located directly below a bottom of one of the first holes to form one of the first holes to a second depth of one of the first insulation films deeper than the etched first sacrifice film by one layer;
forming a second material film on the sidewall of one of the first holes;
forming a second sacrifice film having a seam or a void in one of the first holes;
anisotropically etching the first sacrifice film and the first insulation film directly below the bottom of one of the first holes via the seam or the void to process the first holes in such a manner that the first holes penetrate through the first stack portion, and forming a plurality of second holes and a plurality of memory holes both penetrating through the first stack portion in the first direction around the first holes;
forming first pillar portions made of an insulation material in the second holes, respectively;
forming a plurality of first column bodies each including a semiconductor layer and a memory film in the respective memory hoes;
removing the first sacrifice film located below the first material film in one of the first holes to form a first space between the first insulation films adjacent to each other in the first direction;
forming a second insulation film in the first space;
forming a third sacrifice film in the first holes;
removing the first sacrifice films in the first stack portion to form a second space between the first insulation films adjacent to each other in the first direction;
forming a plurality of electrode films made of a conductive material in a plurality of the second spaces, respectively;
removing the third sacrifice film; and
forming a conductive material in the first holes to form a plurality of contacts respectively connected to the electrode films.

11. The method of claim 10, further comprising, after formation of the second holes and the memory holes and before formation of the first pillar portions:
forming a fourth sacrifice film in the first holes, the second holes, and the memory holes;
forming a fifth insulation film on the first stack portion;
forming a second stack portion by alternately stacking a plurality of fifth sacrifice films and a plurality of sixth insulation films in the first direction on the fifth insulation film;
forming a plurality of third holes penetrating through the second stack portion in the first direction and reaching the fifth insulation film, above the first holes to correspond to the first holes, respectively;
forming a third material film on a sidewall of one of the third holes;
forming a fourth material film on the sidewall of one of the third holes;
forming a sixth sacrifice film having a seam or a void in one of the third holes;
anisotropically etching the fifth insulation film directly below a bottom of one of the third holes via the seam or the void to make the third holes communicate with the fourth sacrifice film in the first holes; and
removing the fourth sacrifice film in the first holes via the third holes.

12. The method of claim 10, further comprising, separately from a first substrate including the first stack portion:
forming a plurality of semiconductor elements on a second substrate;
forming an interlayer dielectric film covering the semiconductor elements;
forming a wiring layer electrically connected to the semiconductor elements and partly exposed from the interlayer dielectric film; and
bonding the first substrate and the second substrate to each other to electrically connect the wiring layer and the contacts to each other.

13. The method of claim 10, further comprising, before formation of the second material film, forming a first narrowing film selectively in an opening of one of the first holes to make the opening of one of the first holes narrower.

14. The method of claim 11, further comprising, before formation of the fourth material film, forming a second narrowing film selectively in an opening of one of the third holes to make the opening of one of the third holes narrower.

15. The method of claim 10, wherein the second sacrifice film is a silicon nitride film.

16. The method of claim 10, wherein the third sacrifice film is amorphous silicon.

17. The method of claim 11, wherein the fourth sacrifice film is carbon.
